(19) United States
(12) Patent Application Publication
(10) Pub. No.: US 2019/0074273 A1
(43) Pub. Date: Mar. 7, 2019

(54) SEMICONDUCTOR DEVICE AND MANUFACTURING METHOD THEREOF

(71) Applicant: Renesas Electronics Corporation, Tokyo (JP)

(72) Inventors: Wataru SUMIDA, Ibaraki (JP); Akihiro SHIMOMURA, Ibaraki (JP)

(21) Appl. No.: 16/033,252

(22) Filed: Jul. 12, 2018

(30) Foreign Application Priority Data
Sep. 4, 2017 (JP) 2017-169324

(51) Int. Cl. H01L 27/02; H01L 29/06; H01L 29/10; H01L 29/417; H01L 29/423; H01L 29/78; H01L 29/66; H01L 21/28; H01L 21/265; H01M 10/42; H02J 7/00

(52) U.S. Cl. CPC H01L 27/0255; H02J 2007/004; H01L 29/1095; H01L 29/41741; H01L 29/4236; H01L 29/42368; H01L 29/7813; H01L 29/7805; H01L 29/66734; H01L 21/28211; H01L 21/26513; H01M 10/425; H02J 7/0029; H01M 2010/4271; H02J 2007/0037; H01L 29/0696

(57) ABSTRACT

A source electrode can be patterned well in response to the densification of a semiconductor device. A first MOS transistor element is formed in a first element region and a second MOS transistor element is formed in a second element region. A first source electrode is arranged so as to straddle a first gate electrode and cover a first source layer located on both one side and the other side in a gate length direction with the first gate electrode interposed. A second source electrode is arranged so as to straddle a second gate electrode and cover a second source layer located on both one side and the other side in the gate length direction with the second gate electrode interposed.

### CROSS-REFERENCE TO RELATED APPLICATIONS

The disclosure of Japanese Patent Application No. 2017-169324 filed on Sep. 4, 2017 including the specification, drawings and abstract is incorporated herein by reference in its entirety.

### BACKGROUND

The present invention: relates to a semiconductor device and a manufacturing method of the semiconductor device; and is suitably applicable to a semiconductor device having a field-effect type MOS transistor element as a bidirectional switching element for example.

As a semiconductor device for a protection circuit to protect a secondary battery such as a lithium-ion battery against overcharge, over-discharge, and the like for example, there is a semiconductor device using a field-effect type MOS (Metal Oxide Semiconductor) transistor element as a switching element capable of switching a bidirectional current path.

In order to make it possible to switch a bidirectional current path, a first MOS transistor element and a second MOS transistor element, those being vertical and having parasitic diodes respectively, are coupled electrically in series. As Patent Literatures disclosing such a semiconductor device, there are Patent Literature 1 and Patent Literature 2.

In Patent Literature 1 and Patent Literature 2, proposed is a semiconductor device formed by alternately arranging a first MOS transistor element and a second MOS transistor element, those being vertical respectively, in a chip (semiconductor substrate).

In the first MOS transistor element, one first gate electrode and another first gate electrode are arranged apart from each other. A first source layer and a first drain layer are formed between the one first gate electrode and the other first gate electrode.

In the second MOS transistor element, one second gate electrode and another second gate electrode are arranged apart from each other. A second source layer and a second drain layer are formed between the one second gate electrode and the other second gate electrode.

The first drain layer and the second drain layer are formed in a semiconductor layer over a semiconductor substrate. A first source electrode coupled electrically to the first source layer and a second source electrode coupled electrically to the second source layer are arranged alternately over the surface of the semiconductor layer. Here, Patent Literature 3 discloses a vertical type MOS transistor element.

### PATENT LITERATURE

Patent Literature 1: Japanese Unexamined Patent Application Publication No. 2006-147700

Patent Literature 2: Japanese Unexamined Patent Application Publication No. 2007-201338

Patent Literature 3: Japanese Unexamined Patent Application Publication No. 2010-258252

### SUMMARY

In a semiconductor device, a first source electrode is formed so as to cover a first source layer located between one first gate electrode and another first gate electrode, those being arranged apart from each other, and the like. Further, a second source electrode is formed so as to cover a second source layer located between one second gate electrode and another second gate electrode, those being arranged apart from each other, and the like.

A semiconductor device having a protection circuit is also required to be densified in order to correspond to the downsizing and high-performance of portable equipment or the like using a secondary battery. An interval between one first (second) gate electrode and another first (second) gate electrode is required to be shortened in response to the densification of the semiconductor device.

The first (second) source electrode however is formed so as to cover a region located between the one first (second) gate electrode and the other first (second) gate electrode. As a result, the patterning of the first (second) source electrode comes to be difficult from the viewpoint of patterning the first (second) source electrode into a desired shape.

Other problems and novel features will be obvious from the descriptions and attached drawings in the present specification.

A semiconductor device according to an embodiment has a semiconductor substrate of a first conductivity type, a semiconductor layer of the first conductivity type, a first element region and a second element region, a plurality of first transistor elements, a plurality of second transistor elements, an interlayer insulating film, a first source electrode, and a second source electrode. The semiconductor layer is formed over the semiconductor substrate so as to be in contact with the semiconductor substrate. The first element region and the second element region are defined alternately in the semiconductor layer. Each of the first transistor elements is formed in the first element region and has a first gate electrode, a first drain, and a first source. Each of the second transistor elements is formed in the second element region and has a second gate electrode, a second drain, and a second source. The interlayer insulating film is formed so as to cover the first transistor elements and the second transistor elements. The first source electrode is formed over the interlayer insulating film and coupled electrically to the first sources. The second source electrode is formed over the interlayer insulating film apart from the first source electrode and coupled electrically to the second sources. The first drains and the second drains are coupled electrically through the semiconductor substrate. In the first element region, the first gate electrodes extend in a first direction and are arranged apart from each other in a second direction intersecting with the first direction. The first source electrode is arranged so as to straddle the first gate electrodes and cover parts of the semiconductor layer located on both one side and the other side in the second direction with the first gate electrodes interposed.

A manufacturing method of a semiconductor device according to another embodiment comprises the following steps. A semiconductor layer of a first conductivity type is formed over a semiconductor substrate of the first conductivity type. A first element region and a second element region are defined alternately in the semiconductor layer. A plurality of first transistor elements each of which has a first gate electrode and a first drain and a first source, those being coupled electrically to the semiconductor substrate, are formed in the first element region and also a plurality of second transistor elements each of which has a second gate electrode and a second drain and a second source, those being coupled electrically to the semiconductor substrate, are formed in the second element region. An interlayer insulating film is formed so as to cover the first transistor elements and the second transistor elements. Over the interlayer insulating film, a first source electrode coupled electrically to the first source in each of the first transistor elements is formed and also a second source electrode coupled electrically to the second source in each of the second transistor elements is formed. At the step of forming the first transistor elements, the first gate electrodes extend in a first direction and are formed apart from each other in a second direction intersecting with the first direction. At the step of forming the first source electrode, the first source electrode is formed so as to straddle the first gate electrodes and cover parts of the semiconductor layer located on both one side and the other side in the second direction with the first gate electrodes interposed.

By a semiconductor device according to an embodiment, it is possible to obtain a semiconductor device having a first source electrode and a second source electrode which are conformable to densification.

By a manufacturing method of a semiconductor device according to another embodiment, it is possible to pattern a first source electrode and a second source electrode well.

### BRIEF DESCRIPTION OF THE DRAWINGS

FIG. 1 is a view showing an example of a protection circuit to which a semiconductor device according to an embodiment is applied.

FIG. 2 is a plan view showing an example of a planar pattern mainly of a first source electrode and a second source electrode in a semiconductor device according to First Embodiment.

FIG. 3 is a plan view showing an example of a planar pattern mainly of first gate electrodes, second gate electrodes, and plugs, those being arranged below a first source electrode and a second source electrode according to the present embodiment.

FIG. 4 is a sectional view showing a cross-sectional structure taken on the cutting line IV-IV in FIG. 2 according to the present embodiment.

FIG. 5 is a sectional view showing current paths for explaining the operation of a semiconductor device according to the present embodiment.

FIG. 6 is a sectional view showing a step in a manufacturing method of a semiconductor device according to the present embodiment.

FIG. 7 is a sectional view showing a step carried out after the step shown in FIG. 6 according to the present embodiment.

FIG. 8 is a sectional view showing a step carried out after the step shown in FIG. 7 according to the present embodiment.

FIG. 9 is a sectional view showing a step carried out after the step shown in FIG. 8 according to the present embodiment.

FIG. 10 is a sectional view showing a step carried out after the step shown in FIG. 9 according to the present embodiment.

FIG. 11 is a sectional view showing a step carried out after the step shown in FIG. 10 according to the present embodiment.

FIG. 12 is a sectional view showing a step carried out after the step shown in FIG. 11 according to the present embodiment.

FIG. 13 is a sectional view showing a step carried out after the step shown in FIG. 12 according to the present embodiment.

FIG. 14 is a sectional view showing a step carried out after the step shown in FIG. 13 according to the present embodiment.

FIG. 15 is a sectional view showing a step carried out after the step shown in FIG. 14 according to the present embodiment.

FIG. 16 is a sectional view showing a step carried out after the step shown in FIG. 15 according to the present embodiment.

FIG. 17 is a sectional view showing a step carried out after the step shown in FIG. 16 according to the present embodiment.

FIG. 18 is a partial sectional view of a semiconductor device according to a first comparative example.

FIG. 19 is a plan view of a semiconductor device according to a second comparative example.

FIG. 20 is a sectional view taken on the cutting line XX-XX in FIG. 19.

FIG. 21 is a sectional view for explaining the effect caused by a semiconductor device according to the present embodiment.

FIG. 22 is a sectional view showing a cross-sectional structure of a semiconductor device according to Second Embodiment.

FIG. 23 is a sectional view showing current paths for explaining the operation of a semiconductor device according to the present embodiment.

FIG. 24 is a sectional view showing a step in a manufacturing method of a semiconductor device according to the present embodiment.

FIG. 25 is a sectional view showing a step carried out after the step shown in FIG. 24 according to the present embodiment.

### DETAILED DESCRIPTION

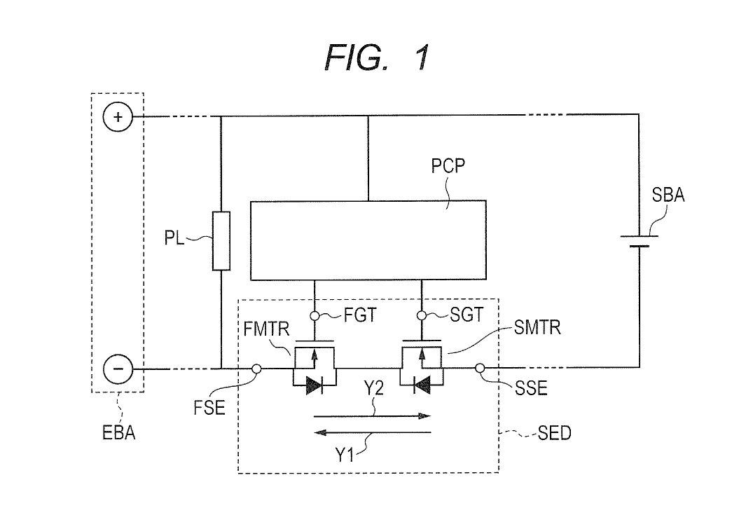

Firstly, a usage state of a semiconductor device is explained. An example of a protection circuit of a secondary battery SBA is shown in FIG. 1. For example, a controller PCP and a semiconductor device SED are coupled to a secondary battery SBA such as a lithium-ion battery. In the semiconductor device SED, a first MOS transistor element FMTR and a second MOS transistor element SMTR are coupled electrically in series.

Firstly, when the secondary battery SBA is charged, an external power source EBA is coupled. Further, both the first MOS transistor element FMTR and the second MOS transistor element SMTR are in an ON state in the semiconductor device SED by a signal from the controller PCP. The secondary battery SBA is charged by feeding electric current from the external power source EBA in the direction of the arrow Y1.

When the charge is completed, the controller PCP detects the completion of the charge and the first MOS transistor element FMTR is in an OFF state. In the first MOS transistor element FMTR of the OFF state, a parasitic diode is directed in a direction opposite to the flow of the electric current. As a result, a circuit is cut off and overcharge to the secondary battery SBA is prevented.

Secondary, when the secondary battery SBA is discharged, a load PL is coupled. Further, both the first MOS transistor element FMTR and the second MOS transistor element SMTR are in an ON state in the semiconductor device SED by a signal from the controller PCP. Electricity is discharged to the load PL by feeding electric current from the secondary battery SBA in the direction of the arrow Y2.

When the discharge is completed, the controller PCP detects the completion of the discharge and the second MOS transistor element SMTR is in an OFF state. In the second MOS transistor element SMTR of the OFF state, a parasitic diode is directed in a direction opposite to the flow of the electric current. As a result, the circuit is cut off and over-discharge from the secondary battery SBA is prevented.

A semiconductor device SED having a first MOS transistor element FMTR and a second MOS transistor element SMTR is explained hereunder.

### First Embodiment

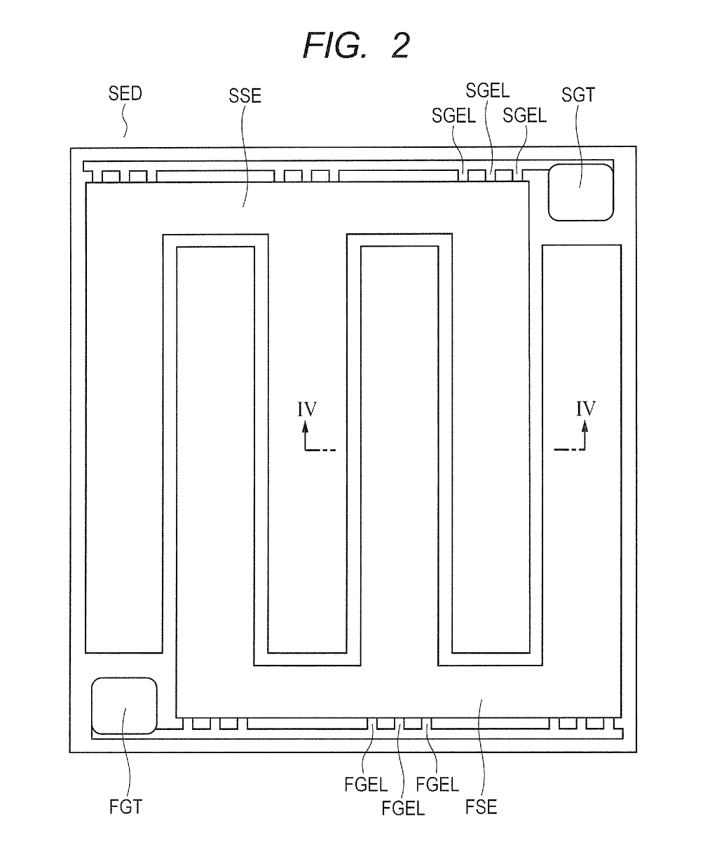

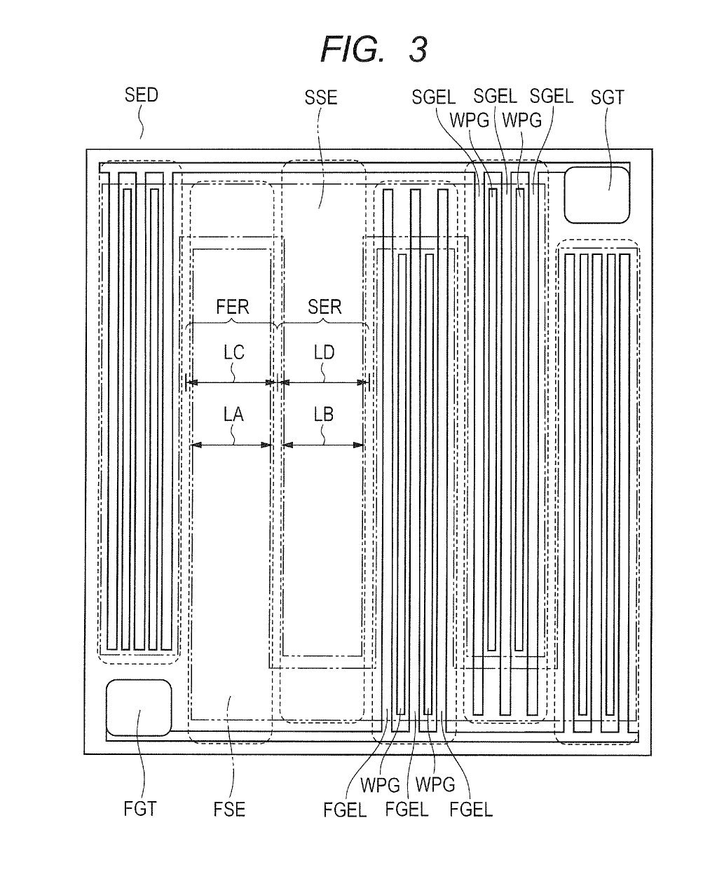

A semiconductor device according to First Embodiment is explained. As shown in FIGS. 2 and 3, over the surface of a semiconductor device SED, a first gate terminal FGT, a second gate terminal SGT, a first source electrode FSE, and a second source electrode SSE are arranged. The first gate terminal FGT is arranged at a corner on an end of a diagonal and the second gate terminal SGT is arranged at a corner on the other end of the diagonal.

In FIG. 3 here, parts of a first gate electrode FGEL and a second gate electrode SGEL are omitted in order to eliminate the complexity of the figure. The first source electrode FSE and the second source electrode SSE have pectinate shapes respectively and are arranged so as to engage with each other. The structure of the semiconductor device SED is explained in more detail.

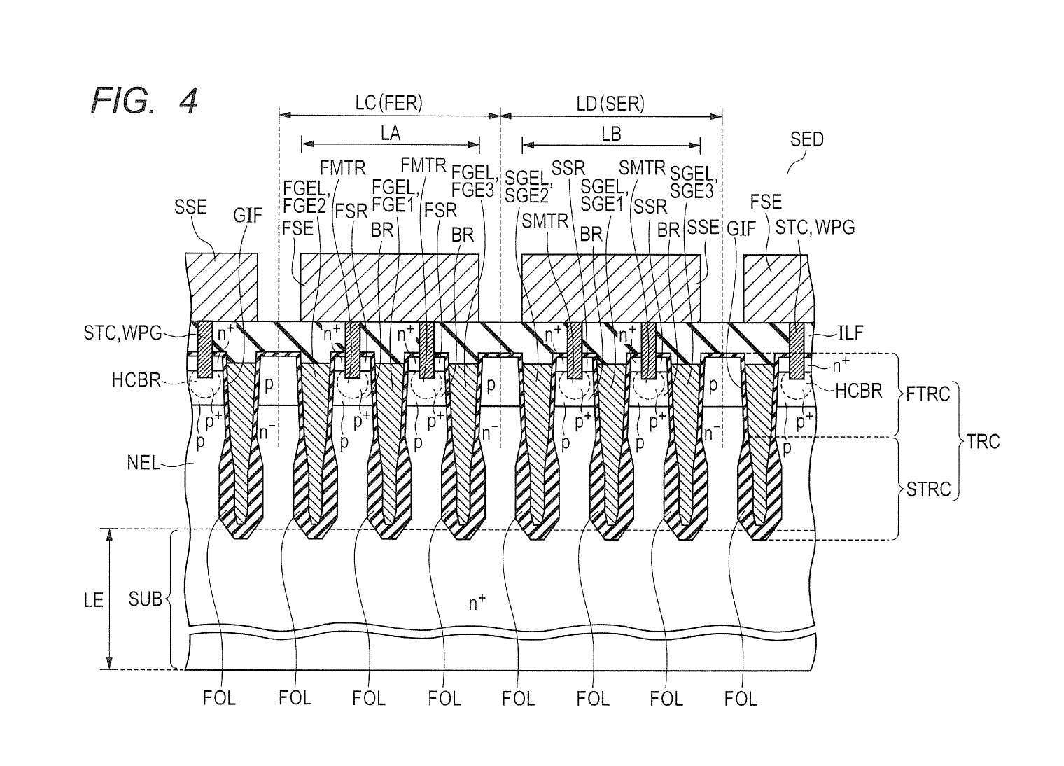

As shown in FIGS. 3 and 4, in the semiconductor device SED, an n-type epitaxial layer NEL is formed so as to be in contact with the surface of an n⁺-type semiconductor substrate SUB. The impurity concentration of the semiconductor substrate SUB is higher than the impurity concentration of the n-type epitaxial layer NEL. A first element region FER and a second element region SER are alternately defined in the n-type epitaxial layer NEL.

A first MOS transistor element FMTR is formed in the first element region FER. A first gate electrode FGEL is formed in a trench TRC extending from the surface of the n-type epitaxial layer NEL and reaching the semiconductor substrate with a gate oxide film GIF or a field oxide film FOL interposed. Here, three first gate electrodes FGEL are arranged in the first element region FER.

Each of the three first gate electrodes FGEL is formed so as to extend in one direction (first direction). A first gate electrode FGE2 (first gate electrode second section) is formed apart from a first gate electrode FGE1 (first gate electrode first section) arranged in the center on one side in a gate length direction (second direction) intersecting with the extending direction. A first gate electrode FGE3 (first gate electrode third section) is formed apart from the first gate electrode FGE1 on the other side in the gate length direction. A first gate electrode FGEL of each first MOS transistor element FMTR is coupled electrically to the first gate terminal FGT.

A first source layer FSR of an n-type and a base layer BR of a p-type are formed at each of parts of the n-type epitaxial layer NEL located between the respective first gate electrodes FGE1 to FGE3. The first source layer FSR is formed in a range from the surface of the n-type epitaxial layer NEL to a predetermined depth. The base layer BR is located right under the first source layer FSR. The base layer BR is formed in a range from the bottom of the first source layer FSR to a predetermined depth. A part of the n-type epitaxial layer NEL (semiconductor substrate SUB) located right under the base layer BR is a common region as a drain layer of each first MOS transistor element FMTR.

A second MOS transistor element SMTR is formed in the second element region SER. A second gate electrode SGEL is formed in a trench TRC extending from the surface of the n-type epitaxial layer NEL and reaching the semiconductor substrate with a gate oxide film GIF or a field oxide film FOL interposed. Here, three second gate electrodes SGEL are arranged in the second element region SER.

Each of the three second gate electrodes SGEL is formed so as to extend in one direction (first direction). A second gate electrode SGE2 (second gate electrode second section) is formed apart from a second gate electrode SGE1 (second gate electrode first section) arranged in the center on one side in a gate length direction (second direction) intersecting with the extending direction. A second gate electrode SGE3 (second gate electrode third section) is formed apart from the second gate electrode SGE1 on the other side in the gate length direction. A second gate electrode SGEL of each second MOS transistor element SMTR is coupled electrically to the second gate terminal SGT.

A second source layer SSR of an n-type and a base layer BR of a p-type are formed at each of parts of the n-type epitaxial layer NEL located between the respective second gate electrodes SGE1 to SGE3. The second source layer SSR is formed in a range from the surface of the n-type epitaxial layer NEL to a predetermined depth. The base layer BR is located right under the second source layer SSR. The base layer BR is formed in a range from the bottom of the second source layer SSR to a predetermined depth. A part of the n-type epitaxial layer located right under the base layer BR is a common region as a drain layer of each second MOS transistor element SMTR.

An interlayer insulating film ILF is formed so as to cover the first MOS transistor element FMTR and the second MOS transistor element SMTR. A plug WPG is formed so as to penetrate the interlayer insulating film ILF. The first source electrode FSE is formed over the surface of a part of the interlayer insulating film ILF located in the first element region FER. The first source electrode FSE is coupled electrically to the first source layer FSR of the first MOS transistor element FMTR through the plug WPG. The second source electrode SSE is formed over the surface of a part of the interlayer insulating film ILF located in the second element region SER. The second source electrode SSE is coupled electrically to the second source layer SSR of the second MOS transistor element SMTR through a plug WPG.

The first source electrode FSE is arranged so as to straddle the first gate electrode FGE1 and cover the first source layer FSR (n-type epitaxial layer NEL) located respectively on one side and the other side in the gate length direction with the first gate electrode FGE1 interposed. The second source electrode SSE is arranged so as to straddle the second gate electrode SGE1 and cover the second source layer SSR (n-type epitaxial layer NEL) located respectively on one side and the other side in the gate length direction with the second gate electrode SGE1 interposed.

The first source electrode FSE and the second source electrode SSE are arranged alternately apart from each other. The thicknesses of the first source electrode FSE and the second source electrode SSE are about 1 μm for example. On this occasion, the width (length LC) of the first element region FER and the width (length LD) of the second element region SER are about 3 μm. An interval between the first source electrode FSE and the second source electrode SSE is about 1 μm. The width (length LA) of the first source electrode FSE and the width (length LB) of the second source electrode SSE are about 2 μm. Further, the thickness (length LE) of the semiconductor substrate is about 100 μm.

Here, the numerical values are only examples. When the thicknesses of the first source electrode FSE and the second source electrode SSE are about 5 μm for example, the interval between the first source electrode FSE and the second source electrode SSE is about 5 μm.

The flow of electric current accompanying the operation of the semiconductor device stated above is explained hereunder. As it has been explained in the beginning, when a secondary battery SBA is charged or discharged, both a first MOS transistor element FMTR and a second MOS transistor element SMTR are in an ON state in a semiconductor device SED by a signal from a controller PCP.

When the secondary battery SBA is charged, the electric current flows from the second MOS transistor element SMTR to the first MOS transistor element FMTR. On the other hand, when the secondary battery SBA is discharged, the electric current flows from the first MOS transistor element FMTR to the second MOS transistor element SMTR (refer to FIG. 1).

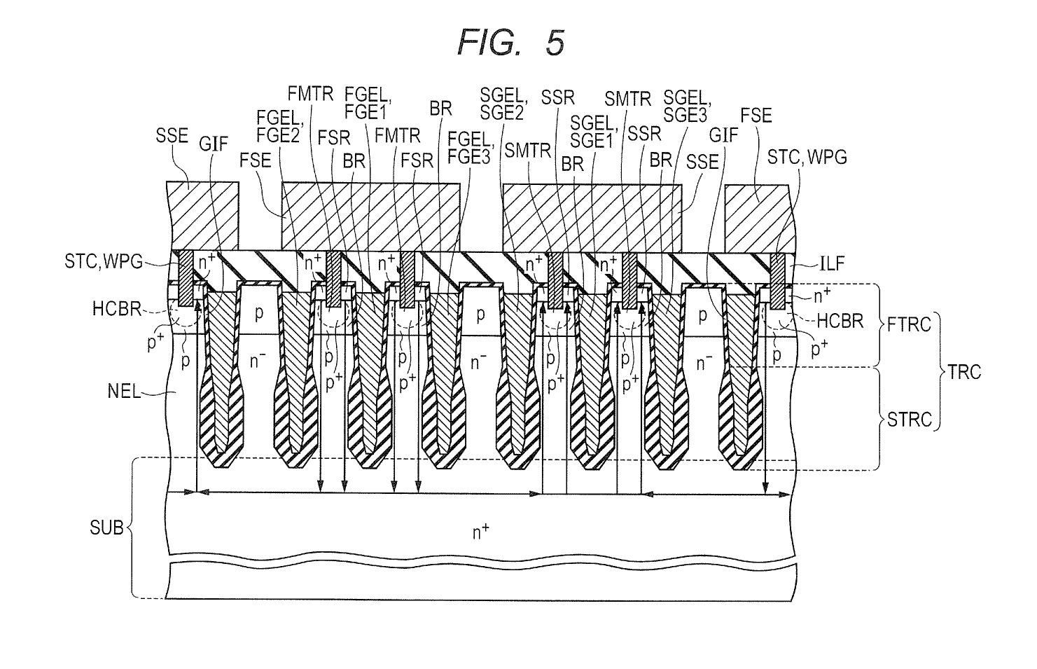

Here, the flow of electric current when the secondary battery SBA is discharged is explained in more detail. A load PL carries out predetermined function by the discharge of the secondary battery SBA. On this occasion, as shown in FIG. 5, the electric current flows from a first source electrode FSE to a first source layer FSR, a channel region, an n-type epitaxial layer NEL (first drain), a semiconductor substrate SUB, the n-type epitaxial layer NEL (second drain), a channel region, a second source layer SSR, and a second source electrode SSE in sequence (refer to the arrows).

The electric current having flown in a first MOS transistor element FMTR (first source layer FSR and n-type epitaxial layer NEL) located on the right side right under the first source electrode FSE flows mainly in a second MOS transistor element SMTR (n-type epitaxial layer NEL and second source layer SSR) located on the left side right under the second source electrode SSE.

On the other hand, the electric current having flown in a first MOS transistor element FMTR (first source layer FSR and n-type epitaxial layer NEL) located on the left side right under the first source electrode FSE flows mainly in a second MOS transistor element SMTR (n-type epitaxial layer NEL and second source layer SSR) located on the right side right under the second source electrode SSE.

When the discharge of the secondary battery SBA is completed, the second MOS transistor elements SMTR are in an OFF state, the flow of the electric current is intercepted by a parasitic diode, and the over-discharge from the secondary battery SBA is prevented (refer to FIG. 1). Here, the flow of the electric current in the case of charge is a flow opposite to the flow of the electric current in the case of discharge.

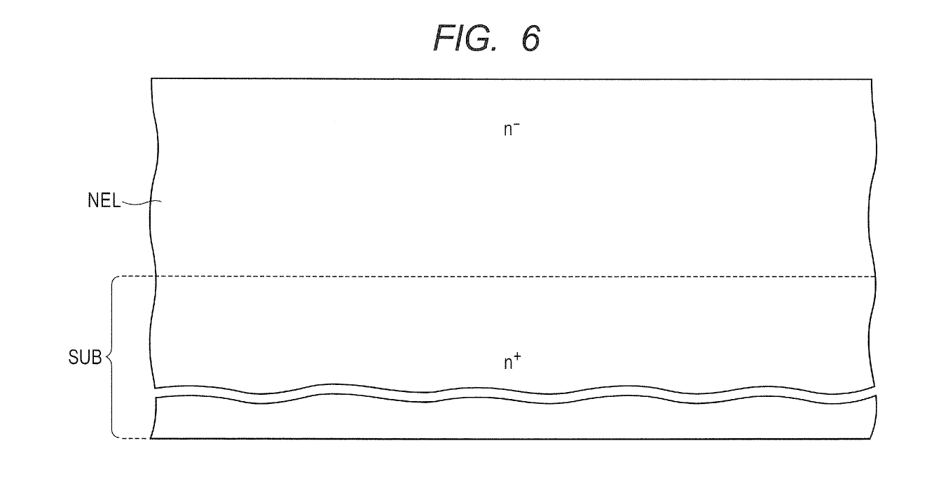

An example of a manufacturing method of the semiconductor device stated above is explained hereunder. Firstly, as shown in FIG. 6, an n-type epitaxial layer NEL is formed over the surface of an n⁺-type semiconductor substrate SUB by an epitaxial growth method. Successively, for example, a silicon oxide film (not shown in the figure) acting as a mask is formed so as to cover the n-type epitaxial layer NEL.

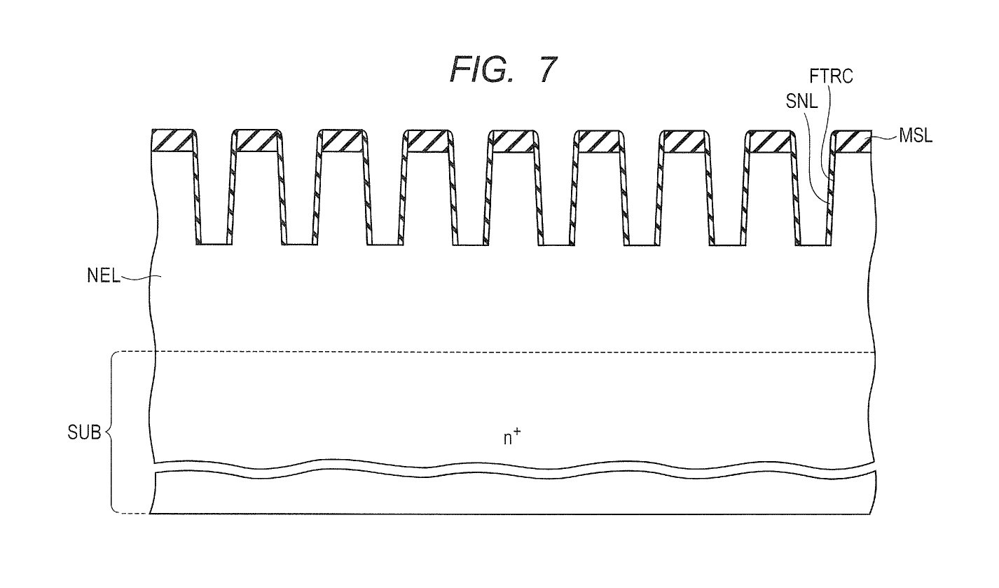

Successively, a first trench FTRC (refer to FIG. 7) is formed by applying predetermined photolithographic treatment and etching treatment for forming a trench. Successively, a silicon nitride film (not shown in the figure) is formed so as to cover the surface of the first trench FTRC and the like.

Successively, anisotropic etching treatment is applied to the silicon nitride film. As a result, as shown in FIG. 7, the parts of the silicon nitride film located over the bottom of the first trench FTRC and the upper surface of the silicon nitride film SNL respectively are removed while the parts of the silicon nitride film SNL located over the sidewall surface of the first trench FTRC and the like remain.

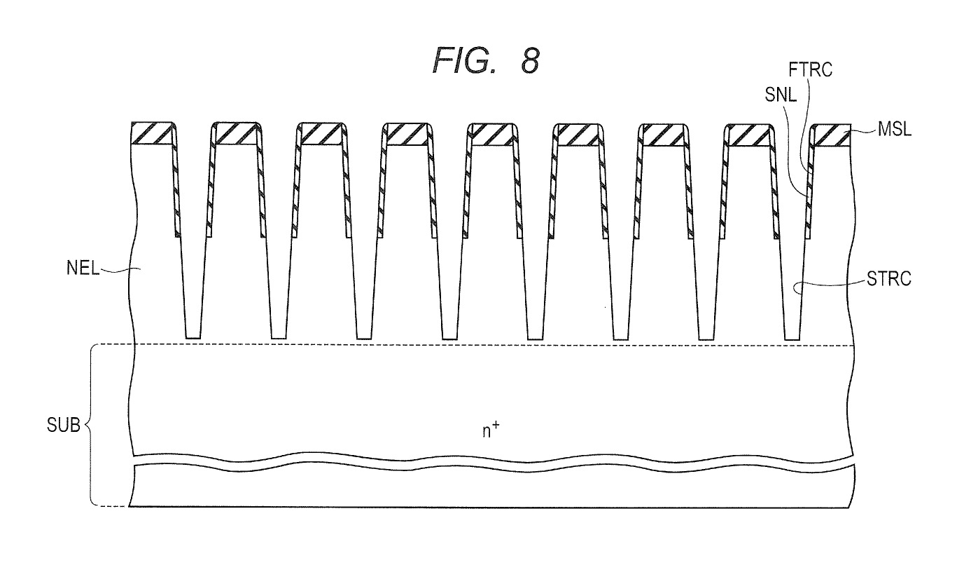

Successively, as shown in FIG. 8, a second trench STRC communicating with the first trench FTRC is formed by applying etching treatment to the part of the n-type epitaxial layer NEL exposed at the bottom of the first trench FTRC with a silicon oxide film MSL and the silicon nitride film SNL used as etching masks.

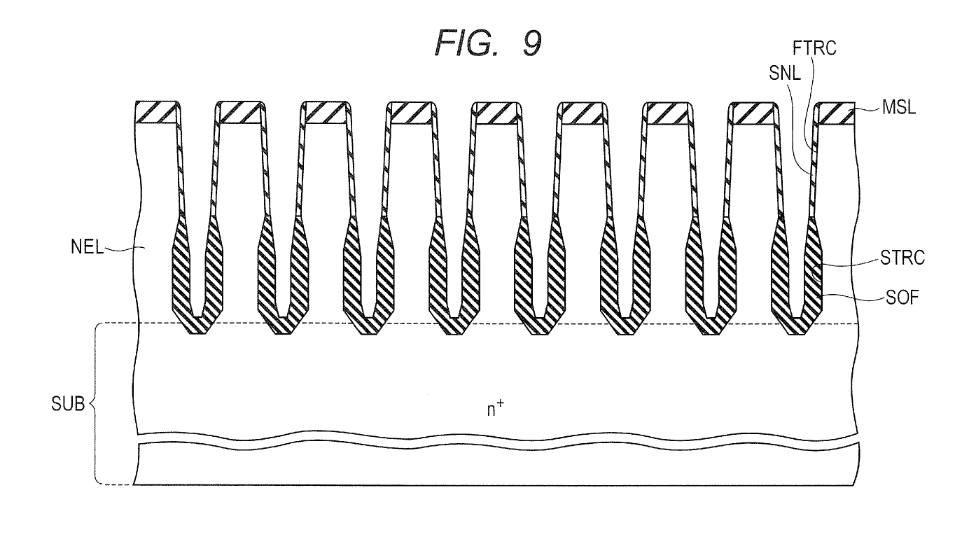

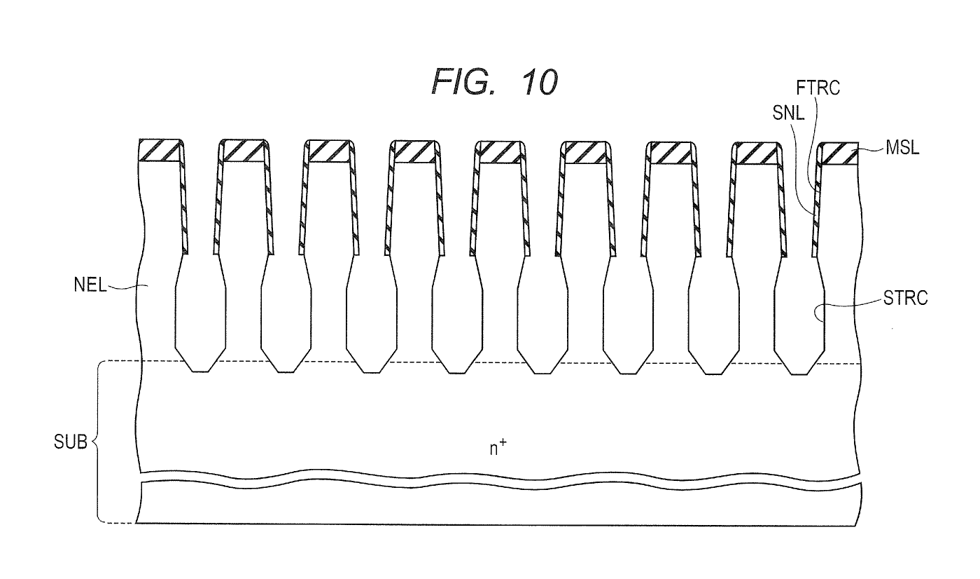

Successively, as shown in FIG. 9, by applying thermal oxidation treatment, the part of the n-type epitaxial layer NEL exposed from the sidewall surface of the second trench STRC and the like is oxidized and a sacrificial oxide film SOF is formed. Successively, as shown in FIG. 10, by applying predetermined etching treatment, the sacrificial oxide film SOF is removed and the n-type epitaxial layer NEL is exposed from the sidewall surface of the second trench STRC and the like.

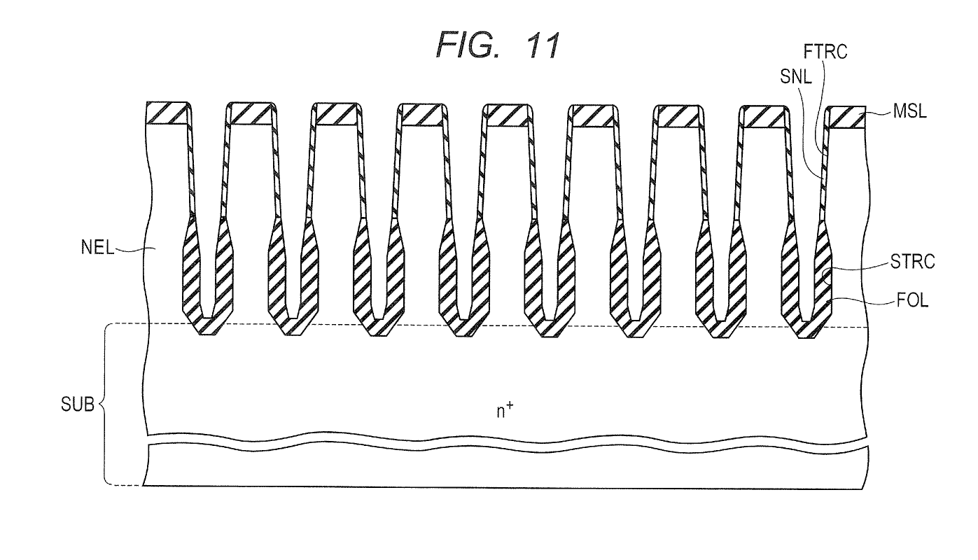

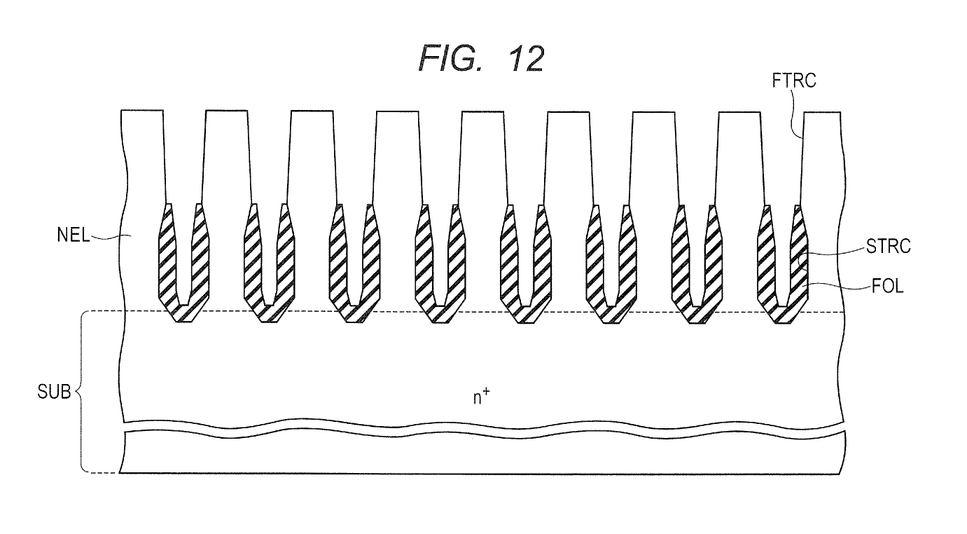

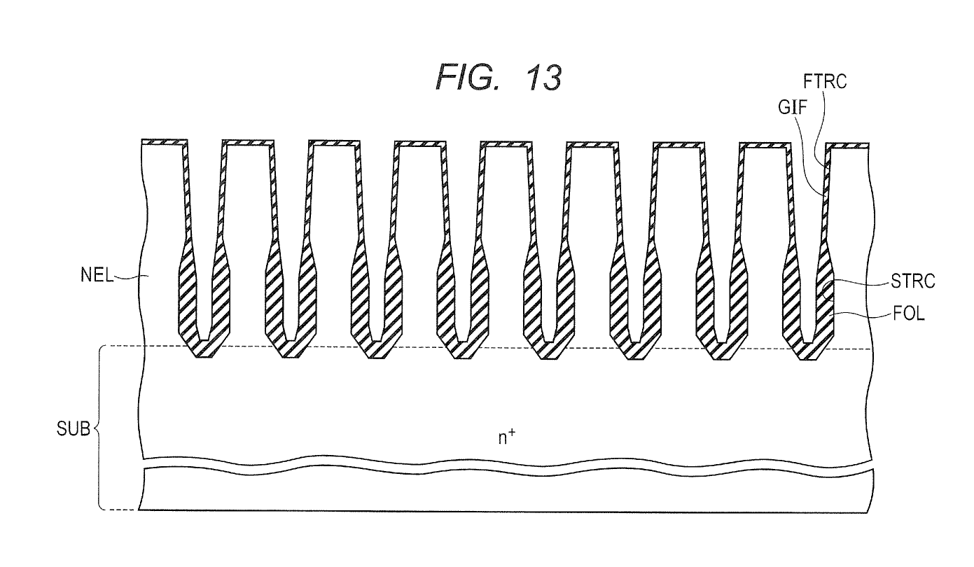

Successively, as shown in FIG. 11, by applying thermal oxidation treatment, the part of the n-type epitaxial layer NEL exposed from the sidewall surface of the second trench STRC and the like is oxidized and a field oxide film FOL is formed. Successively, as shown in FIG. 12, by applying predetermined etching treatment, the silicon nitride film SNL and the silicon oxide film MSL are removed. Successively, as shown in FIG. 13, by applying thermal oxidation treatment, the part of the n-type epitaxial layer exposed from the sidewall surface of the first trench FTRC and the like is oxidized and a gate oxide film GIF is formed.

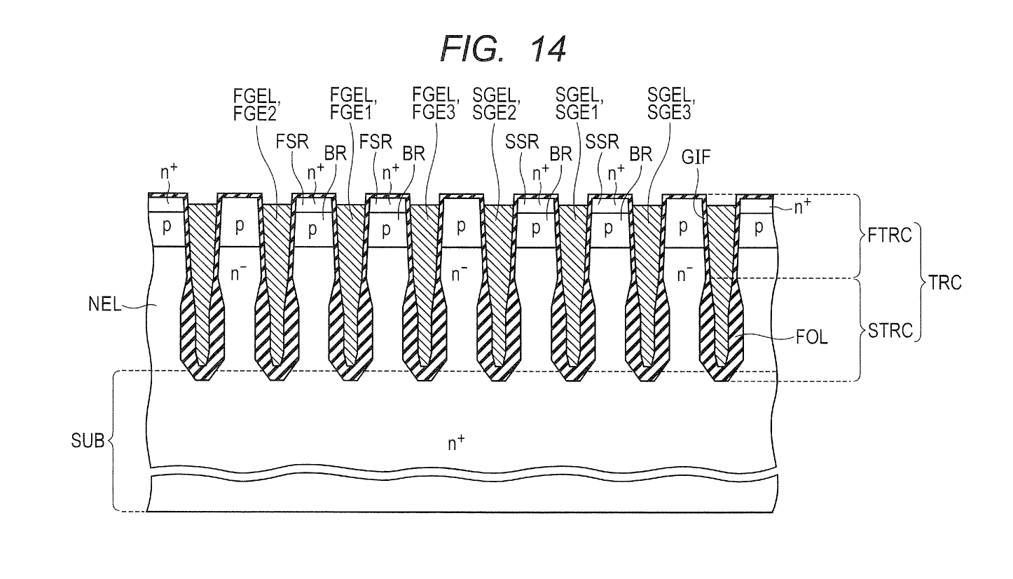

Successively, in a process of filling the trench TRC, a polysilicon film (not shown in the figure) is formed so as to cover the n-type epitaxial layer NEL. Successively, by applying anisotropic etching treatment to the polysilicon film, the part of the polysilicon film located over the upper surface of the n-type epitaxial layer NEL and the like is removed. As a result, as shown in FIG. 14, the part of the polysilicon film remaining in the trench TRC is formed as a first gate electrode FGEL and a second gate electrode SGEL.

Successively, by implanting p-type impurities over the whole surface of the n-type epitaxial layer NEL, a base layer BR is formed. Successively, by applying predetermined photolithographic treatment, a photoresist pattern (not shown in the figure) is formed. Successively, by implanting n-type impurities with the photoresist pattern used as an implantation mask, a first source layer FSR and a second source layer SSR, those being n⁺-types, are formed.

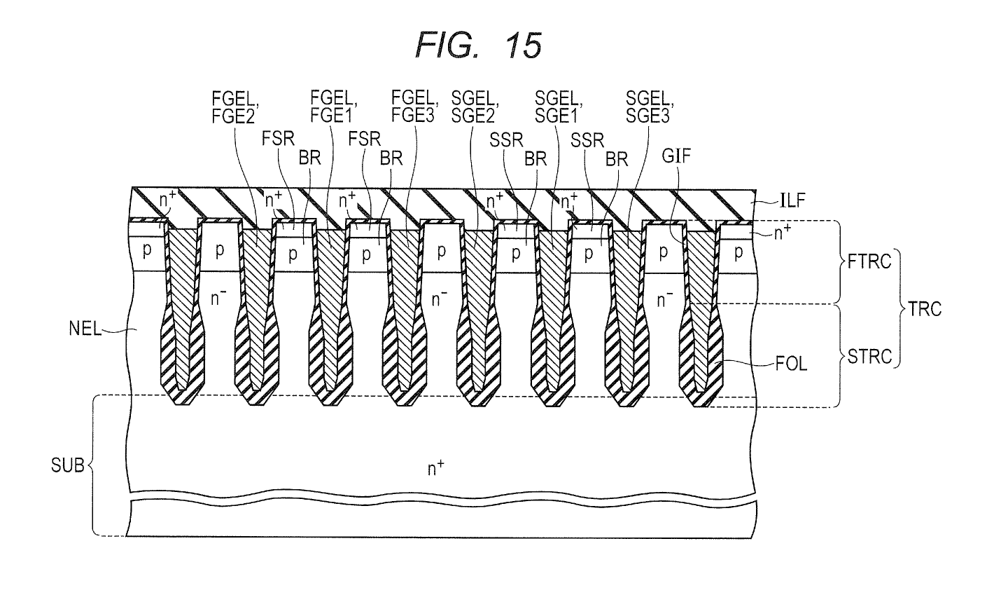

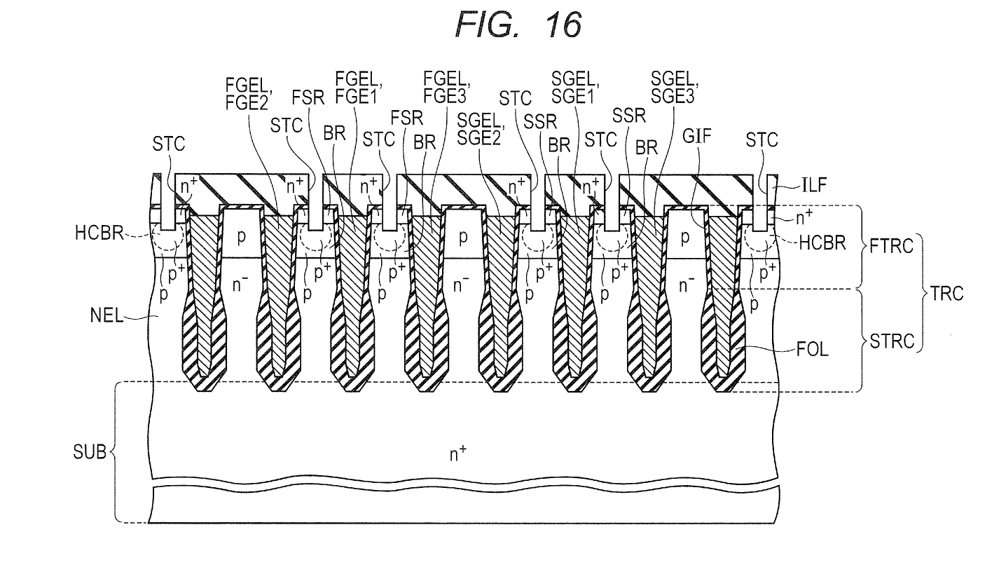

Successively, as shown in FIG. 15, an interlayer insulating film ILF comprising a silicon oxide film or the like for example is formed so as to cover the first gate electrode FGEL and the second gate electrode SGEL. Successively, predetermined photolithographic treatment and etching treatment are applied to the interlayer insulating film ILF. As a result, as shown in FIG. 16, a source trench STC to expose the first source layer FSR and the base layer BR and a source trench STC to expose the second source layer SSR and the base layer BR are formed.

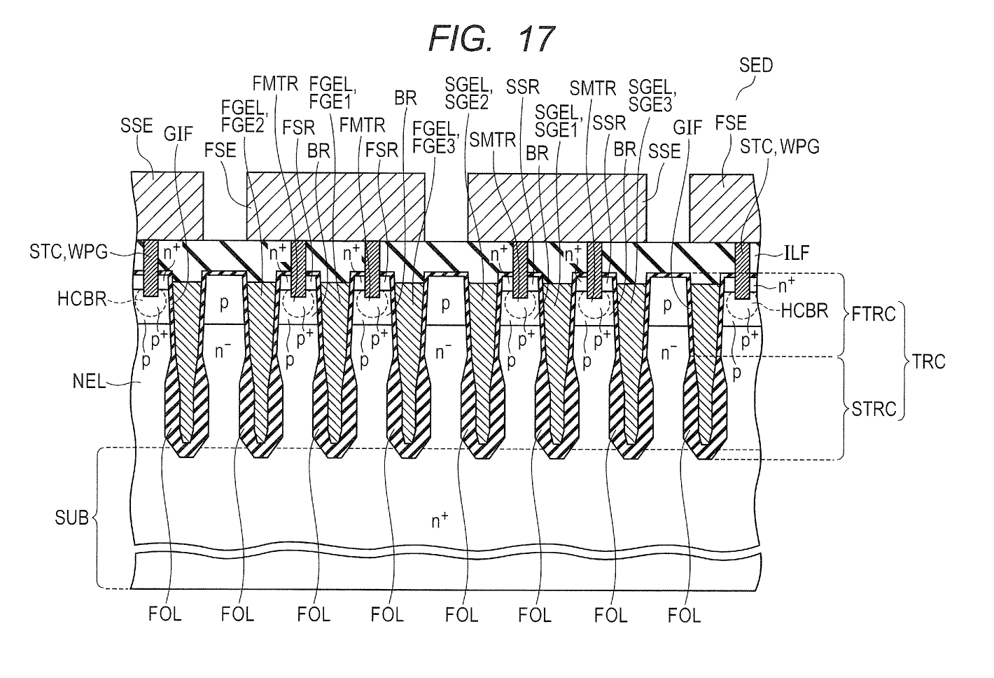

Successively, by implanting p-type impurities through the source trench STC, a high-concentration base layer HCBR is formed. Successively, by filling the interior of the source trench STC with a tungsten film or the like for example, a plug WPG (refer to FIG. 17) is formed.

Successively, an aluminum film (not shown in the figure) having a predetermined thickness is formed so as to cover the interlayer insulating film ILF by a sputtering method for example. Successively, predetermined photolithographic treatment and etching treatment are applied to the aluminum film. As a result, as shown in FIG. 17, a first source electrode FSE and a second source electrode SSE are formed. The first source electrode FSE and the second source electrode SSE are formed alternately apart from each other. In this way, the main part of the semiconductor device is completed.

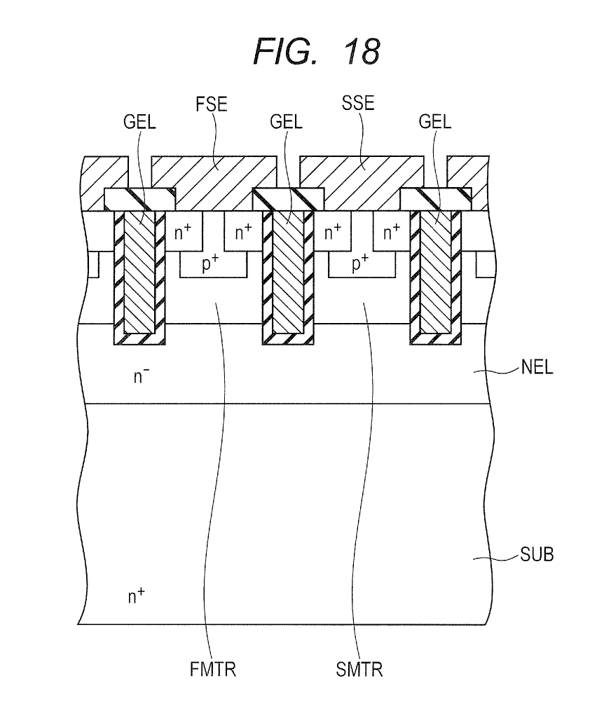

Effects by the semiconductor device stated above are explained hereunder in comparison with semiconductor devices according to comparative examples. Firstly, a first comparative example is explained. As shown in FIG. 18, in a semiconductor device according to the first comparative example, a plurality of gate electrodes GEL are formed apart from each other. A first MOS transistor element FMTR is formed between one gate electrode GEL and another gate electrode GEL adjacent to each other. A second MOS transistor element SMTR is formed between the other gate electrode GEL and still another gate electrode GEL adjacent to each other.

A first source electrode FSE is formed so as to cover a region (source layer) located between the one gate electrode GEL and the other gate electrode GEL. A second source electrode SSE is formed so as to cover a region (source layer) located between the other gate electrode GEL and the still other gate electrode GEL.

In the semiconductor device according to the first comparative example, either of the first source electrode FSE and the second source electrode SSE is formed so as to cover a region (source layer) located between a gate electrode GEL and a gate electrode GEL adjacent to each other.

Consequently, if you try to shorten an interval between a gate electrode GEL and a gate electrode GEL adjacent to each other in order to respond to the densification of a semiconductor device, the respective widths of the first source electrode FSE and the second source electrode SSE also have to be shortened.

From the viewpoint of photolithography and etching however, it comes to be increasingly difficult to pattern the first source electrode FSE and the second source electrode SSE into desired sizes so as not to come excessively close to each other, as an interval between a gate electrode GEL and a gate electrode GEL adjacent to each other narrows. Consequently, the narrowing of the widths of the first source electrode FSE and the second source electrode SSE is limited.

In the semiconductor device SED stated above in comparison with the semiconductor device according to the first comparative example, the first source electrode FSE is arranged so as to straddle the first gate electrode FGE1 and cover the first source layer FSR located on both one side and the other side in the gate length direction with the first gate electrode FGE1 interposed. The second source electrode SSE is arranged so as to straddle the second gate electrode SGE1 and cover the second source layer SSR located on both one side and the other side in the gate length direction with the second gate electrode SGE1 interposed.

Consequently, in comparison with the first comparative example, the width of the first source electrode FSE and the width of the second source electrode SSE can be secured when an interval between the adjacent first gate electrodes FGEL and an interval between the adjacent second gate electrodes SGEL are shortened. As a result, it is possible to: pattern the first source electrode FSE and the second source electrode SSE well; and respond to the densification of a semiconductor device.

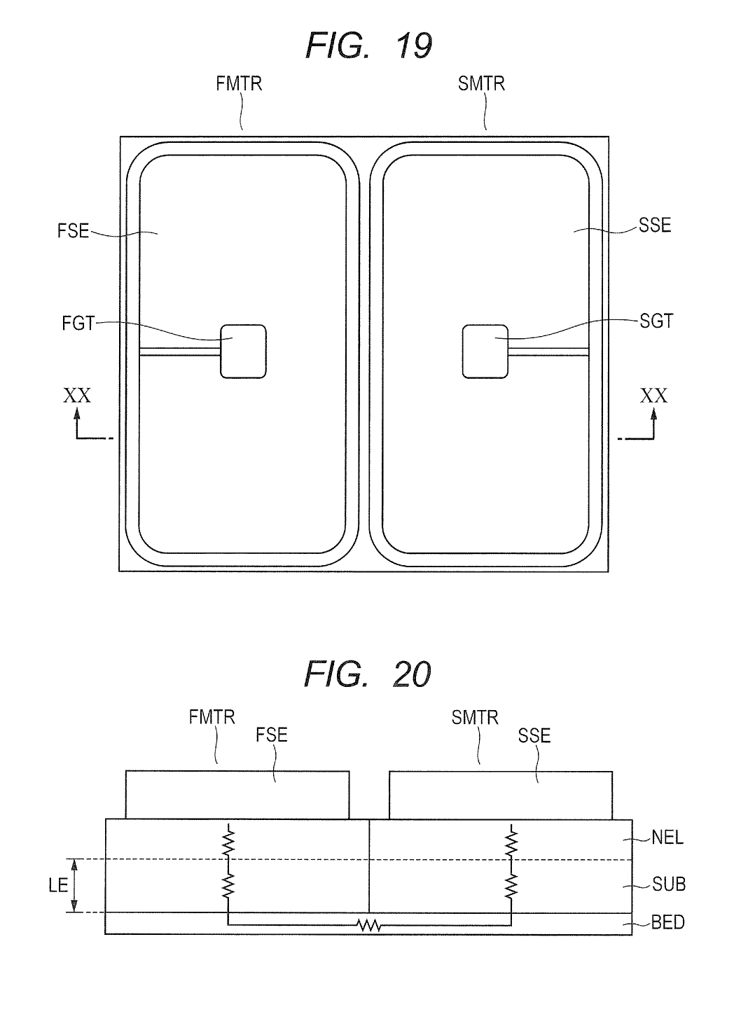

A second comparative example is explained hereunder. As shown in FIGS. 19 and 20, in a semiconductor device according to the second comparative example, a first MOS transistor element FMTR and a second MOS transistor element SMTR are formed individually. In the first MOS transistor element FMTR, a first source electrode FSE and a first gate terminal FGT are formed. In the second MOS transistor element SMTR, a second source electrode SSE and a second gate terminal SGT are formed.

The first source electrode FSE and the second source electrode SSE are arranged over an n-type epitaxial layer NEL. The n-type epitaxial layer NEL is formed over the surface of a semiconductor substrate SUB. A back electrode BED is formed at the back of the semiconductor substrate SUB.

In the semiconductor device according to the second comparative example, electric current flows either from the first MOS transistor element FMTR to the second MOS transistor element SMTR or from the second MOS transistor element SMTR to the first MOS transistor element FMTR.

On this occasion, as shown in FIG. 20, as components of on resistance when electric current flows, there are mainly channel resistance when electric current flows in a channel (not shown in the figures), Epi resistance when the electric current flows in the n-type epitaxial layer NEL, substrate resistance when electric current flows in the semiconductor substrate SUB, and metal resistance when electric current flows in the back electrode BED. Here, in FIG. 20, the Epi resistance and the channel resistance are shown as one resistance component.

In the semiconductor device according to the second comparative example, since electric current flows in the semiconductor substrate SUB in a vertical direction in particular, as substrate resistance, substrate resistance corresponding to twice the thickness (length LE) of the semiconductor substrate SUB relates to on resistance.

Here, when you try to reduce substrate resistance in order to reduce on resistance in a semiconductor device, it is necessary to reduce the thickness (length LE) of a semiconductor substrate SUB. If the thickness of a semiconductor substrate SUB is reduced however, the semiconductor substrate SUB may warp undesirably. Further, the semiconductor substrate SUB tends to break undesirably. Furthermore, if you try to increase the thickness of a back electrode BED in order to reduce on resistance, the process of forming the back electrode BED is complicated undesirably and manufacturing cost is caused to increase.

In comparison with the semiconductor device according to the second comparative example, in the semiconductor device SED stated above, electric current flows in a first source electrode FSE, a first source layer FSR, a channel region, an n-type epitaxial layer NEL (first drain layer), a semiconductor substrate SUB, the n-type epitaxial layer NEL (second drain layer), a channel region, a second source layer SSR, and a second source electrode SSE (refer to the arrows in FIG. 5).

From the paths of the electric current, as the components of on resistance, there are mainly channel resistance when electric current flows in the channel region, Epi resistance when electric current flows in the n-type epitaxial layer NEL, and substrate resistance when electric current flows in the semiconductor substrate SUB. In particular, in the semiconductor device SED stated above, electric current flows in the semiconductor substrate SED in a lateral direction.

As stated above, according to the flowability of electric current, electric current having flown in the first MOS transistor element FMTR (first source layer FSR and n-type epitaxial layer NEL) located on the right side right under the first source electrode FSE flows mainly in the second MOS transistor element SMTR (n-type epitaxial layer NEL and second source layer SSR) located on the left side right under the second source electrode SSE (refer to FIG. 5).

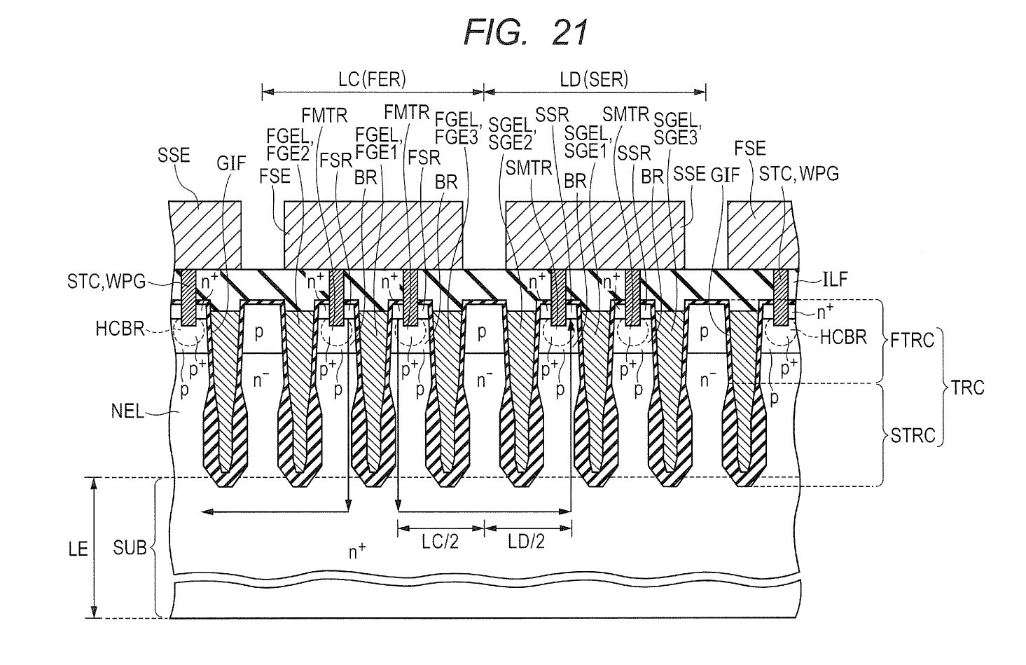

Here, as shown in FIG. 21, the width of a first element region FER is defined as a length LC and the width of a second element region SER is defined as a length LD. Then the distance (length) of flow in a semiconductor substrate SUB from the first MOS transistor element FMTR toward the second element region SER in the first element region FER is estimated to be about the half of the length LC. The distance (length) of flow in the semiconductor substrate SUB toward the second MOS transistor element SMTR in the second element region SER is estimated to be about the half of the length LD.

In the semiconductor device SED stated above, the thickness (length LE) of the semiconductor substrate SUB is set so that the distance (length (LC/2+LD/2)) of flow in the semiconductor substrate SUB may be shorter than the distance (length 2LE) of vertical flow in the semiconductor substrate SUB. In other words, the thickness of the semiconductor substrate SUB is set so as to satisfy the expression “length LC+length LD<length 4×LE”. For example, when the length LE (thickness of a semiconductor substrate SUB) is about 100 μm, length LC+length LD is less than 400 μm. As a result, the substrate resistance of the semiconductor substrate SUB can be reduced in comparison with the semiconductor device according to the second comparative example in which electric current flows vertically in the semiconductor substrate SUB.

Further, in the semiconductor device SED stated above, the first MOS transistor element FMTR and the second MOS transistor element SMTR are coupled electrically through the semiconductor substrate SUB. Consequently, the metal resistance of the back electrode BED can be reduced in comparison with the semiconductor device according to the second comparative example in which they are coupled electrically through the back electrode BED.

Furthermore, in the semiconductor device according to the first comparative example, the first MOS transistor element FMTR and the second MOS transistor element SMTR are coupled electrically through the n-type epitaxial layer NEL having an impurity concentration lower than the impurity concentration of the semiconductor substrate SUB.

In comparison with the semiconductor device according to the first comparative example, in the semiconductor device SED stated above, the first MOS transistor element FMTR and the second MOS transistor element SMTR are coupled electrically through the semiconductor substrate SUB having an impurity concentration higher than the impurity concentration of the n-type epitaxial layer NEL. Consequently, on resistance between the first MOS transistor element FMTR and the second MOS transistor element SMTR can be reduced in comparison with the semiconductor device according to the first comparative example.

### Second Embodiment

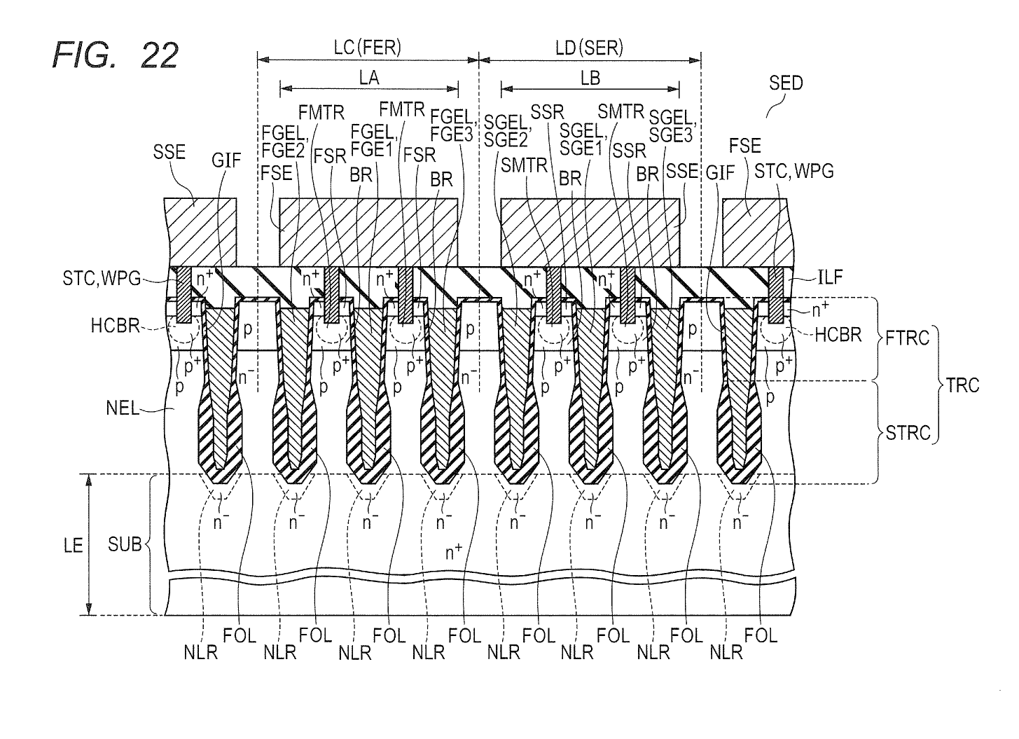

A semiconductor device according to Second Embodiment is explained. As shown in FIG. 22, in a semiconductor device SED, an impurity region NLR of an n-type having an impurity concentration lower than the impurity concentration of a semiconductor substrate SUB is formed in a region of the semiconductor substrate SUB located right under a field oxide film FOL. Here, since the other configurations are similar to the configurations of the semiconductor device shown in FIGS. 2 to 4, identical members are represented by an identical code and are not explained repeatedly except when necessary.

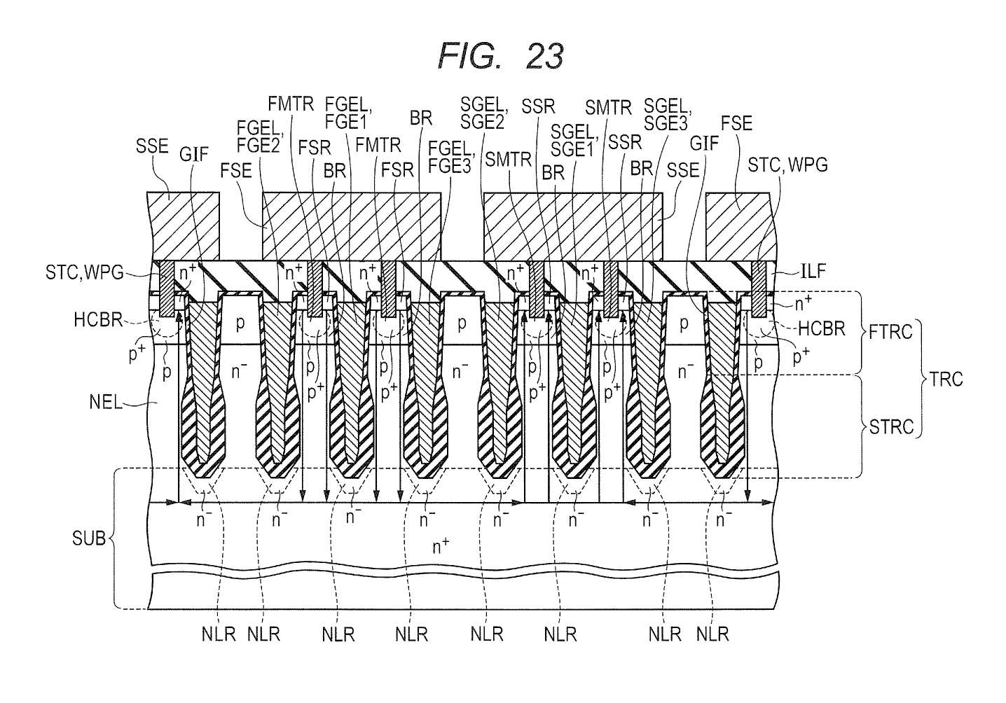

The flow of electric current accompanying the operation of the semiconductor device stated above is explained hereunder. The flow of electric current in the semiconductor device SED is the same as the flow of electric current (refer to FIG. 5) in the semiconductor device SED stated earlier. Here, the flow of electric current when a secondary battery SBA is discharged is explained in more detail. As shown in FIG. 23, electric current flows from a first source electrode FSE to a first source layer FSR, a channel region, an n-type epitaxial layer NEL (first drain layer), a semiconductor substrate SUB, the n-type epitaxial layer NEL (second drain layer), a channel region, a second source layer SSR, and a second source electrode SSE in sequence (refer to the arrows).

When the discharge of the secondary battery SBA is completed, a second MOS transistor element SMTR is in an OFF state, the flow of electric current is intercepted by a parasitic diode, and over-discharge from the secondary battery SBA is prevented (refer to FIG. 1). Here, the flow of the electric current in the case of charge is a flow opposite to the flow of the electric current in the case of discharge.

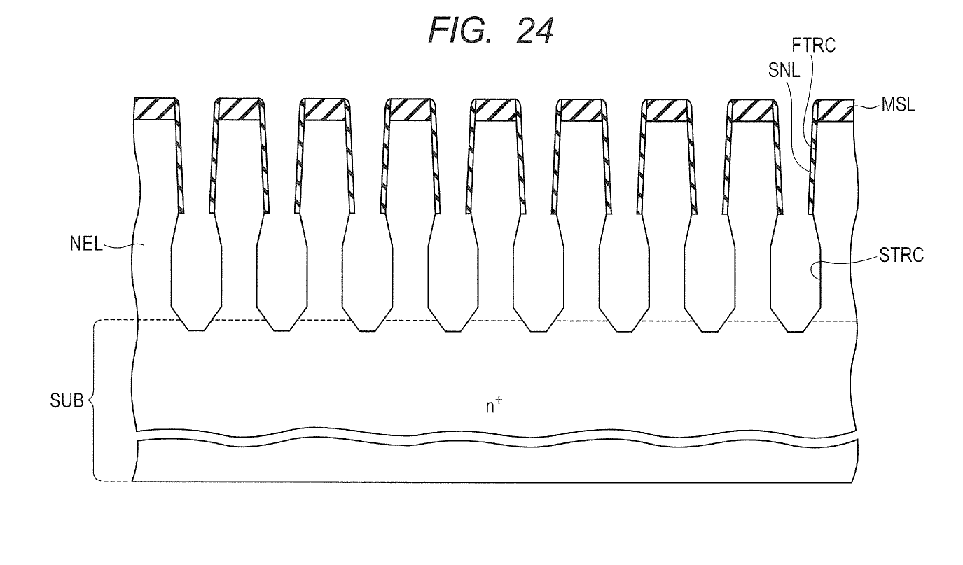

An example of a manufacturing method of the semiconductor device stated above is explained hereunder. Firstly, through steps similar to the steps shown in FIGS. 6 to 10, as shown in FIG. 24, an n-type epitaxial layer NEL and a semiconductor substrate SUB are exposed from the sidewall surface of a second trench STRC.

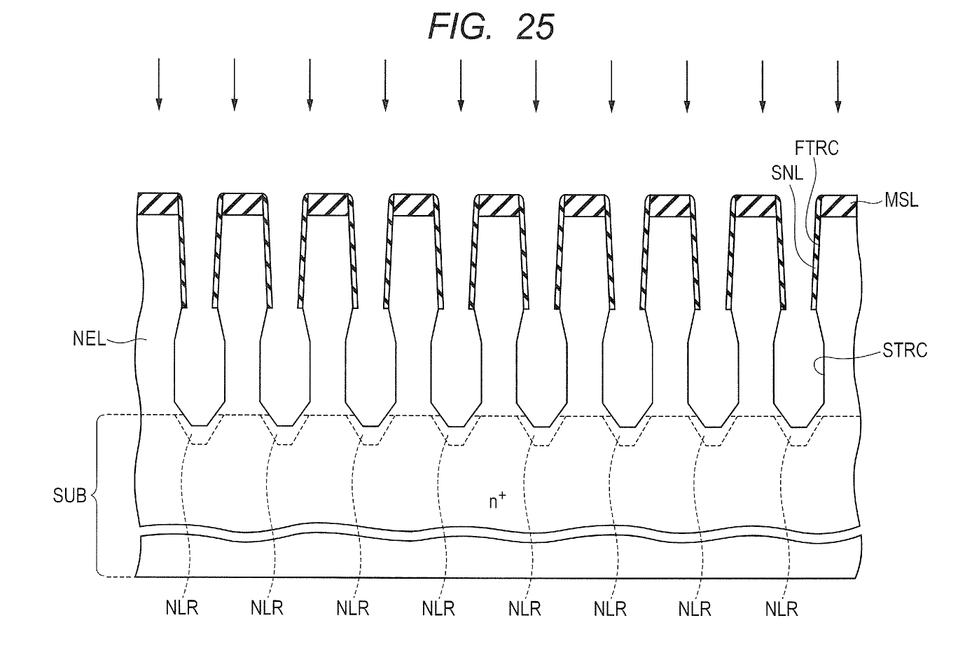

Successively, as shown in FIG. 25, by implanting p-type impurities through a first trench FTRC and the second trench STRC, an impurity region NLR of an n⁻-type is formed mainly at a part of the semiconductor substrate SUB located right under the second trench STRC. The impurity concentration of the impurity region NLR is lower than the impurity concentration of the semiconductor substrate SUB. Successively, through steps similar to the steps shown in FIGS. 11 to 17, the semiconductor device SED shown in FIG. 22 is completed.

In the semiconductor device stated above, an impurity region NLR of an n⁻-type having an impurity concentration lower than the impurity concentration of a semiconductor substrate SUB is formed in a region of the semiconductor substrate SUB located right under a field oxide film FOL. Consequently, when a first MOS transistor element FMTR and a second MOS transistor element SMTR are in an OFF state, a depletion layer extending toward the side of the semiconductor substrate SUB can extend toward the side of the semiconductor substrate SUB more than the semiconductor device stated earlier. As a result, it is possible to prevent the withstand voltage of the semiconductor device from deteriorating. Here, in an ON state, electric current flows in the semiconductor substrate SUB and hence the impurity region NLR influences on resistance less.

Further, in the semiconductor device SED stated above, similarly to the semiconductor device stated earlier, the width of a first source electrode FSE and the width of a second source electrode SSE can be secured when an interval between adjacent first gate electrodes FGEL and an interval between adjacent second gate electrodes SGEL are shortened. As a result, it is possible to: pattern the first source electrode FSE and the second source electrode SSE well; and respond to the densification of a semiconductor device.

Furthermore, in the semiconductor device SED stated above, similarly to the semiconductor device stated earlier, the thickness (length LE) of a semiconductor substrate SUB is set so as to satisfy the expression “length LC+length LD<length 4×LE”. Consequently, the substrate resistance of the semiconductor substrate SUB can be reduced in comparison with the semiconductor device according to the second comparative example stated earlier.

Moreover, in the semiconductor device SED stated above, similarly to the semiconductor device stated earlier, a first MOS transistor element FMTR and a second MOS transistor element SMTR are coupled electrically through a semiconductor substrate SUB having an impurity concentration higher than the impurity concentration of an n-type epitaxial layer NEL. Consequently, on resistance between the first MOS transistor element FMTR and the second MOS transistor element SMTR can be reduced in comparison with the semiconductor device according to the first comparative example stated earlier.

Here, in First Embodiment and Second Embodiment, the explanations are made on the basis of the case where the number of first gate electrodes FGEL formed in a first element region FER is set at three and the number of second gate electrodes SGEL formed in a second element region SER is set at three. The numbers of the first gate electrodes FGEL and the second gate electrodes SGEL are not limited to those numbers and four or more first gate electrodes FGEL and four or more second gate electrodes SGEL may also be formed.

The semiconductor devices explained in the embodiments can be combined variously if necessary.

Although the invention established by the present inventors has heretofore been explained concretely on the basis of the embodiments, it goes without saying that the present invention is not limited to the embodiments and can be modified variously within the range not departing from the tenor of the present invention.

What is claimed is:

1. A semiconductor device, comprising:
a semiconductor substrate of a first conductivity type;
a semiconductor layer of the first conductivity type formed over the semiconductor substrate so as to be in contact with the semiconductor substrate;
a first element region and a second element region defined alternately in the semiconductor layer;
a plurality of first transistor elements each of which is formed in the first element region and has a first gate electrode, a first drain, and a first source;
a plurality of second transistor elements each of which is formed in the second element region and has a second gate electrode, a second drain, and a second source;
an interlayer insulating film formed so as to cover the first transistor elements and the second transistor elements;
a first source electrode formed over the interlayer insulating film and coupled electrically to the first sources; and
a second source electrode formed over the interlayer insulating film apart from the first source electrode and coupled electrically to the second sources,
wherein the first drains and the second drains are coupled electrically through the semiconductor substrate, and
wherein, in the first element region,
the first gate electrodes extend in a first direction and are arranged apart from each other in a second direction intersecting with the first direction, and
the first source electrode is arranged so as to straddle the first gate electrodes and cover parts of the semiconductor layer located on both one side and the other side in the second direction with the first gate electrodes interposed.

2. The semiconductor device according to claim 1,
wherein the first element region extends with a first width in the first direction,
wherein the second element region extends with a second width in the first direction, and
wherein the length corresponding to the sum of the first width and the second width is set so as to be shorter than the length corresponding to four times the thickness of the semiconductor substrate.

3. The semiconductor device according to claim 1,
wherein the semiconductor substrate has a first impurity concentration, and
wherein the semiconductor layer has a second impurity concentration lower than the first impurity concentration.

4. The semiconductor device according to claim 3, having an impurity region, being formed at parts of the semiconductor substrate located right under the respective first gate electrodes, and having a third impurity concentration lower than the first impurity concentration.

5. The semiconductor device according to claim 1,
wherein the first gate electrodes include:
a first gate electrode first section;
a first gate electrode second section arranged apart from the first gate electrode first section on one side in the second direction; and
a first gate electrode third section arranged apart from the first gate electrode first section on the other side in the second direction, and
wherein the first source electrode is arranged so as to straddle the first gate electrode first section and cover a part of the semiconductor layer located between the first gate electrode first section and the first gate electrode second section and a part of the semiconductor layer located between the first gate electrode first section and the first gate electrode third section.

6. The semiconductor device according to claim 1,
wherein the first source electrode and the second source electrode are formed pectinately respectively in a plan view, and
wherein the first source electrode and the second source electrode are arranged so as to engage with each other.

7. A manufacturing method of a semiconductor device comprising the steps of:
forming a semiconductor layer of a first conductivity type over a semiconductor substrate of the first conductivity type;
defining a first element region and a second element region alternately in the semiconductor layer;
forming a plurality of first transistor elements each of which has a first gate electrode and a first drain and a first source, those being coupled electrically to the semiconductor substrate, in the first element region and also forming a plurality of second transistor elements each of which has a second gate electrode and a second drain and a second source, those being coupled electrically to the semiconductor substrate, in the second element region;
forming an interlayer insulating film so as to cover the first transistor elements and the second transistor elements; and
over the interlayer insulating film, forming a first source electrode coupled electrically to the first source in each of the first transistor elements and also forming a second source electrode coupled electrically to the second source in each of the second transistor elements,
wherein, at the step of forming the first transistor elements, the first gate electrodes extend in a first direction and are formed apart from each other in a second direction intersecting with the first direction, and
wherein, at the step of forming the first source electrode, the first source electrode is formed so as to straddle the first gate electrodes and cover parts of the semiconductor layer located on both one side and the other side in the second direction with the first gate electrodes interposed.

8. The manufacturing method of a semiconductor device according to claim 7, wherein, at the step of defining the first element region and the second element region, the first element region is defined so as to extend with a first width in the first direction, the second element region is defined so as to extend with a second width in the first direction, and the length corresponding to the sum of the first width and the second width is defined so as to be shorter than the length corresponding to four times the thickness of the semiconductor substrate.

9. The manufacturing method of a semiconductor device according to claim 7, wherein, at the step of forming the semiconductor layer, the impurity concentration of the semiconductor layer is set at an impurity concentration lower than the impurity concentration of the semiconductor substrate.

10. The manufacturing method of a semiconductor device according to claim 7,
wherein the step of forming the first transistor elements includes the steps of:
forming a first trench extending from the surface of the semiconductor layer and reaching the semiconductor substrate; and
forming a first gate electrode over the sidewall surface of the first trench with a first gate insulating film interposed, and
wherein the step of forming the second transistor elements includes the steps of:
forming a second trench extending from the surface of the semiconductor layer and reaching the semiconductor substrate; and
forming a second gate electrode over the sidewall surface of the second trench with a second gate insulating film interposed.

11. The manufacturing method of a semiconductor device according to claim 10, including a step of forming an impurity region of a first conductivity type having an impurity concentration lower than the impurity concentration of the semiconductor substrate at parts of the semiconductor substrate located right under the first trench and the second trench respectively, by implanting impurities of a second conductivity type through the first trench and the second trench after the first trench and the second trench are formed and before the first gate electrode and the second gate electrode are formed.

12. The manufacturing method of a semiconductor device according to claim 7,
wherein the step of forming the first gate electrodes includes a step of forming:
a first gate electrode first section;
a first gate electrode second section apart from the first gate electrode first section on one side in the second direction; and
a first gate electrode third section apart from the first gate electrode first section on the other side in the second direction, and
wherein, at the step of forming the first source electrode, the first source electrode is formed so as to straddle the first gate electrode first section and cover a part of the semiconductor layer located between the first gate electrode first section and the first gate electrode second section and a part of the semiconductor layer located between the first gate electrode first section and the first gate electrode third section.

13. The manufacturing method of a semiconductor device according to claim 7, wherein, at the step of forming the first source electrode and the second source electrode, the first source electrode and the second source electrode are formed pectinately respectively in a plan view and are arranged so as to engage with each other.
